(19) United States
(12) Patent Application Publication
(10) Pub. No.: US 2007/0284714 A1
(43) Pub. Date: Dec. 13, 2007

(54) Electronic Part And Method Of Producing The Same

(75) Inventors: Masayuki Sakakibara, Shizuoka (JP); Masaru Morishita, Shizuoka (JP)

Correspondence Address: DRINKER BIDDLE & REATH (DC), 1500 K STREET, N.W., SUITE 1100, WASHINGTON, DC, 20005-1209, US

(73) Assignee: Hamamatsu Photonics K.K.

(21) Appl. No.: 11/596,055

(22) PCT Filed: May 2, 2005
(86) PCT No.: PCT/JP05/08308

§ 371 Date: Jul. 31, 2007

(30) Foreign Application Priority Data
May 12, 2004 (JP) 2004-142802

(51) Int. Cl. H01L 23/02; H01L 21/00

(52) U.S. Cl. 257/680; 257/678; 438/118; 257/E23.18

(57) ABSTRACT

An electronic component is provided with a base member 1 having a through hole 41 (43) extending from a bottom surface of a recess 15 to a back surface 11_{back}, an electronic element 4 mounted in the recess 15, a lid member 2 closing an aperture of the recess 15, and an adhesive 3 (42) interposed between the lid member 2 and an opening end face of the recess 15, and obstructing the through hole 41 (43) to keep an interior space of the recess in a hermetically-sealed state; the adhesive 3 (42) obstructs a space between the lid member 2 and the base member 1, and the adhesive 3 (42) finally also obstructs the through hole 41 (43) extending from the bottom surface of the recess 15 to the back surface 11_{back} so as to allow air, which could inhibit the obstruction, to escape during production. Since the inhibition of adhesion with the adhesive 3 (42) due to air is prevented in this manner, positional deviation and adhesion failure are suppressed and the obstruction with the adhesive achieves better hermetic sealing in the recess than before. This effect is prominent, particularly, in cases of materials having a plurality of recesses.

### TECHNICAL FIELD

The present invention relates to an electronic component equipped with an electronic element, and a production method thereof and, more particularly, to an optical semiconductor device equipped with an optical semiconductor element, and a production method thereof.

### BACKGROUND ART

There is an electronic component in which an electronic element is housed in a base member (which is obtained by dicing a sheet substrate) and in which a lid is placed on the base member to hermetically seal the interior. Such an electronic component is disclosed, for example, in Patent Document 1 below.

The electronic component described in Patent Document 1 below is constructed as follows: an electronic element (fuse element) is mounted on a bottom surface of each recess in a sheet substrate of ceramic or glass epoxy provided with a plurality of recesses, the electronic element is electrically connected to input/output electrode parts, a sheet lid member is bonded to the substrate with an adhesive of epoxy resin or the like, and thereafter the substrate and the lid member are diced to separate the recesses from each other.

Patent Document 1: Japanese Patent Application Laid-Open No. 2000-311959

### DISCLOSURE OF THE INVENTION

### Problem to be Solved by the Invention

However, the Inventor assembled the electronic component by the production method described in Patent Document 1, and found that during the step of bonding the lid member to the sheet substrate, the sheet lid member slid on the surface of the sheet substrate to cause positional deviation between them. In this case, secure adhesion to the sheet substrate was also inhibited with the adhesive interposed between the sheet lid member and the sheet substrate.

The Inventor analyzed the cause for it and found that air present in each recess failed to escape during the step of bonding the sheet lid member to the sheet substrate, particularly, during a process of covering the plurality of recesses in the sheet substrate by the sheet lid member. Namely, when air acts to escape to the outside through the clearance between the sheet lid member and the sheet substrate, there occurs the phenomenon in which the sheet lid member slides on the surface of the sheet substrate and the adhesive fails to adhere, so as to fail to assure sufficient hermetic sealing in the recess.

In more detail, the production method of the electronic component as described above is likely to cause the positional deviation and adhesion failure, and the electronic component as a product can suffer from the positional deviation and adhesion failure and fail to assure sufficient hermetic sealing.

The present invention has been accomplished in view of the above problem and an object of the invention is to provide an electronic component capable of improving the hermetic sealing, based on reduction in positional deviation and adhesion failure, and a production method of an electronic component capable of suppressing such a phenomenon.

### Means for Solving the Problem

In order to solve the above problem, an electronic component according to the present invention comprises a base member having a through hole extending from a bottom surface of a recess to a back surface; an electronic element mounted in the recess; a lid member closing an aperture of the recess; and an adhesive interposed between the lid member and an opening end face of the recess and obstructing the through hole to keep an interior space of the recess in a hermetically-sealed state.

In the electronic component of the present invention, the adhesive obstructs the space between the lid member and the base member and the adhesive finally also obstructs the through hole penetrating from the bottom surface of the recess to the back surface so as to allow air, which could inhibit the obstruction, to escape during production. Therefore, the inhibition of adhesion with the adhesive due to air is prevented, so as to suppress the positional deviation and adhesion failure, and the obstruction with the adhesive achieves better hermetic sealing in the recess than before. This effect is prominent, particularly, in cases of materials having a plurality of recesses.

Preferably, an aperture on the recess side of the through hole is located near an interior wall of the recess. In this case, since during the production the adhesive located on the opening end face of the recess can readily enter the aperture of the through hole located near the interior wall of the recess, the adhesive efficiently obstructs the through hole, whereby the hermetically-sealed state with the adhesive is more improved than before. This effect is prominent, particularly, in cases of materials having a plurality of recesses.

The electronic component is characterized in that the bottom surface of the recess is polygonal and in that the aperture on the recess side of the through hole is located near a position of an apex of the bottom surface. Since interior wall surfaces (side faces) of the recess come to intersect at the positions of the apexes of the bottom surface, liquid tends to gather in a narrow space such as a space between these side faces. Therefore, in the production the adhesive located on the opening end face of the recess can readily enter the aperture of the through hole through this gathering-prone space, whereby the adhesive efficiently obstructs the through hole and the hermetically-sealed state with the adhesive is more improved than before. This effect is prominent, particularly, in cases of materials having a plurality of recesses.

Preferably, the adhesive continuously hangs down from a region between the lid member and the opening end face, along an interior wall of the recess, and to a region in the through hole. In this case, the adhesive becomes less likely to depart from the interior of the through hole, which improves reliability of hermetic sealing.

Preferably, the bottom surface of the recess has: a lower bottom face to which the electronic element is die-bonded; and an upper bottom face located around the lower bottom face, set nearer the lid member than the lower bottom face, and making a level difference at a border with the lower bottom face, the through hole extends from the upper bottom face to the back surface of the base member, and a diameter of an aperture on the back surface side of the through hole is larger than a diameter of the aperture on the recess side.

In this case, the adhesive flowing from the inner surface side of the recess into the through hole obstructs the through hole on the smaller diameter side, and even if the amount of the adhesive is excessive, the adhesive is less likely to flow over the back surface because the adhesive-receiving space in the through hole becomes larger with travel of the adhesive toward the back surface.

The electronic element is an optical semiconductor element, the lid member is comprised of a material that transmits a major optical component corresponding to the optical semiconductor element, and the base member is comprised of a material having a different transmission characteristic from that of the lid member; the base member is able to block the major light component and the lid member is able to transmit the major light component.

The adhesive is preferably a room temperature curing adhesive; preferably, this adhesive is comprised of a moisture curing silicone resin. Since this adhesive cures at room temperature, there is no need for exposing it under high temperature and it is thus feasible to reduce stress due to a difference between expansion coefficients of the lid member and the base member occurring after bonded. Particularly, the moisture curing silicone resin reacts with hydroxyl (—OH) of the adhering object to effect bonding. The silicone resin still has sufficient flexibility even after cured, and has low hygroscopicity, different from epoxy resin adhesives and others. Furthermore, since it has a property of very high heat resistance among resins, it becomes feasible to prevent peeling of the sheet lid member, a drop of the sheet lid member, or the like during soldering.

Furthermore, since the adhesive cures at room temperature, it can prevent a situation in which air in the recess in the hermetically-sealed state becomes swollen during the curing to generate voids in the adhering surface, so as to cause curing failure. Since the silicone resin is highly transparent to light in the short wavelength range as well, reduction can be suppressed in transmittance of the light corresponding to the optical semiconductor element even if a small amount of the adhesive attaches to a photodetecting portion.

The base member is desirably made of ceramic. Ceramic is a substance with excellent heat resistance and excellent durability and also has an advantage of high adhesion to the silicone resin.

The electronic component is characterized by comprising: an upper electrode pad disposed on the bottom surface of the recess and electrically connected to the electronic element; and a back electrode terminal disposed on the back surface of the base member, and characterized in that the upper electrode pad and the back electrode terminal are electrically connected through a conductor on a depressed surface located in a side of the base member and in that a deepest part of the depressed surface is located outside an exterior edge defining the bottom surface of the recess.

Namely, the electronic element and the upper electrode pad are connected by a bonding wire or the like and the upper electrode pad is connected to the back electrode terminal through the conductor provided on the depressed surface. When the electronic component is placed on a circuit wiring board, the back electrode terminal can be connected onto circuit wiring. The conductor on the depressed surface can be made by perforating a through hole through a substrate and thereafter providing an electroconductive material thereon, and thus production thereof is easy. In this perforating step, the hole including the depressed surface is made at a position off the recess-forming position so as to assure sufficient hermetic sealing in the recess, and thereafter dicing is performed across this hole.

The electronic component is characterized by comprising: an upper electrode pad disposed on the bottom surface of the recess and electrically connected to the electronic element; and a back electrode terminal disposed on the back surface of the base member, and characterized in that the upper electrode pad and the back electrode terminal are electrically connected through a conductor located in the base member and in that the conductor is located outside an exterior edge defining the bottom surface of the recess.

Namely, the electronic element and the upper electrode pad are connected by a bonding wire or the like and the upper electrode pad is connected to the back electrode terminal through the conductor provided so as to be located in the base member. When the electronic component is placed on a circuit wiring board, the back electrode terminal can be connected onto circuit wiring. The conductor located in the base member can be made by perforating a through hole through a substrate serving as a bottom surface in production of the base member, and thereafter putting an electroconductive material in the hole, and thus production is easy. In this perforating step, the hole is made at a position off the recess-forming position so as to assure sufficient hermetic sealing in the recess, and thereafter this hole is filled with the electroconductive material. Then the electroconductive material is covered by a substrate located on the board as the bottom surface to constitute the base member.

A production method of an electronic component according to the present invention comprises a first step of mounting an electronic element in a recess in a base member in which at least one through hole is formed in a bottom surface near an interior wall of the recess; and a second step of bonding a lid member to the base member with a room temperature curing adhesive to close an aperture of the recess in the base member by the lid member. When the aperture is closed by the lid member, air in the recess flows through the through hole to the outside, so as to reduce positional deviation between the lid member and the base member and the adhesion failure with the adhesive. Since the adhesive also enters the interior of the through hole, hermetic sealing in the recess can be further improved. Since the adhesive is of the room temperature curing type, it is also feasible to prevent the situation in which air in the recess in the hermetically-sealed state becomes swollen during the curing to generate voids in the adhering surface, so as to cause curing failure.

Preferably, the first step has a step of preparing a sheet substrate in which a plurality of recesses are formed in one surface, and a step of mounting the electronic element in each of the plurality of recesses; and the second step has a step of applying the room temperature curing adhesive onto an opening end face of the recess, and a step of pasting the sheet substrate and a sheet lid member together with the adhesive to let the adhesive flow down the interior wall of the recess into the at least one through hole extending from the bottom surface of each recess, and thereby obstructing the through hole to form a complex sheet in which an interior space of the recess is kept in a hermetically-sealed state. This production method preferably comprises a step of cutting the complex sheet consisting of the sheet substrate, the sheet lid member, and the adhesive, along a dicing line set on a region between the recesses, and this cutting results in obtaining a plurality of electronic components in each of which the base member and the lid member are pasted together.

Air in each recess flows through the through hole to the outside and, at the same time, the adhesive flows down the interior wall of the recess into the through hole to obstruct it, and is cured at room temperature. By cuffing the complex sheet along the dicing line on the region between the recesses, a plurality of electronic components can be obtained with sufficient hermetic sealing in the recess.

### EFFECT OF THE INVENTION

The electronic component of the present invention enjoys the effect of reduction in positional deviation and adhesion failure and improvement in hermetic sealing. The production method of the electronic component of the present invention enjoys the effect of suppression of positional deviation and adhesion failure and improvement in hermetic sealing.

### BRIEF DESCRIPTION OF THE DRAWINGS

FIG. 1 is a plan view of an optical semiconductor device according to an embodiment of the present invention.

FIG. 2 is a sectional view along line II-II in FIG. 1.

FIG. 3 is a back side view of the optical semiconductor device according to the embodiment of the present invention.

FIG. 4 is a local sectional view of a second embodiment.

FIG. 5 is a plan view of a sheet substrate used in production of an optical semiconductor device.

FIG. 6 is an enlarged view of a through hole forming pattern in FIG. 5.

FIG. 7 is an enlarged view of another through hole forming pattern in FIG. 5.

FIG. 8 is an enlarged view of still another through hole forming pattern in FIG. 5.

FIG. 9 is a perspective view of a sheet substrate before a sheet lid member is bonded thereto.

FIG. 10 is a drawing including an enlarged view (a) of a counterbore, and a sectional view (b) along line B-B of the part shown in (a).

FIG. 11 is a step diagram showing a production step of an optical semiconductor device.

FIG. 12 is a step diagram showing a step subsequent to the step shown in FIG. 11.

### DESCRIPTION OF REFERENCE SYMBOLS

1 base member
2 glass window
3 adhesive
4 photodiode
10 sheet substrate
11 substrate body
12 wall
13 lower wall
14 upper wall
15 recess
16 counterbore
17 marker
20 sheet lid member
21A, 21B, 21C, 21E upper electrode pads
22A, 22B, 22C, 22E bonding wires
24A-24E side electrodes
25A-25E electrode terminals
26A-26F depressed surfaces
30 dicing blade
M optical semiconductor device

### BEST MODE FOR CARRYING OUT THE INVENTION

The preferred embodiments of the present invention will be described below with reference to the drawings. In each embodiment, portions with identical functionality will be denoted by the same reference symbols, without redundant description.

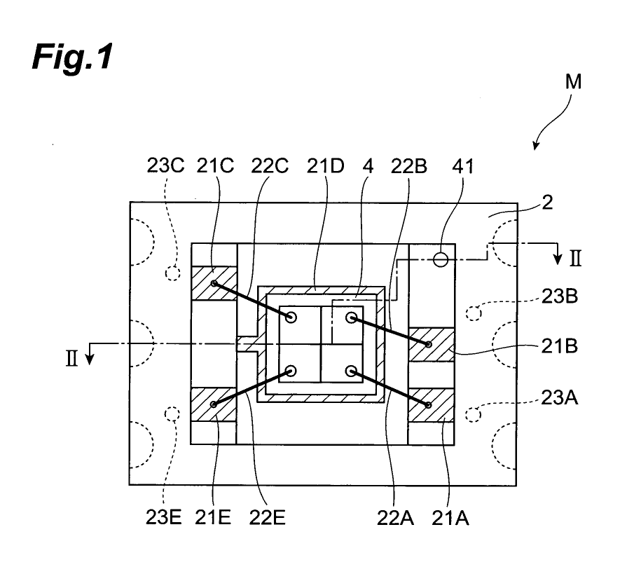

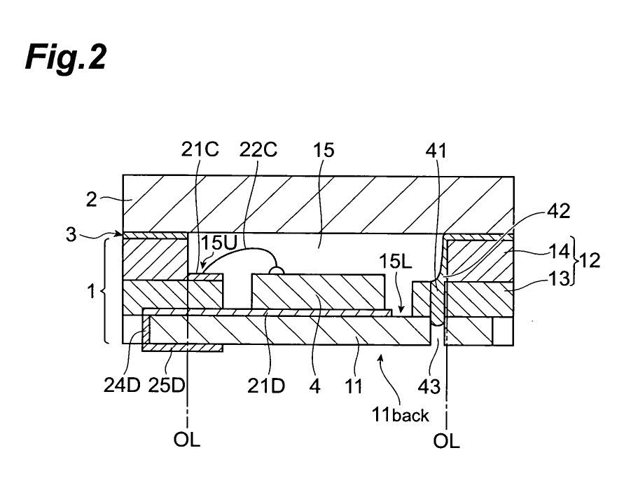

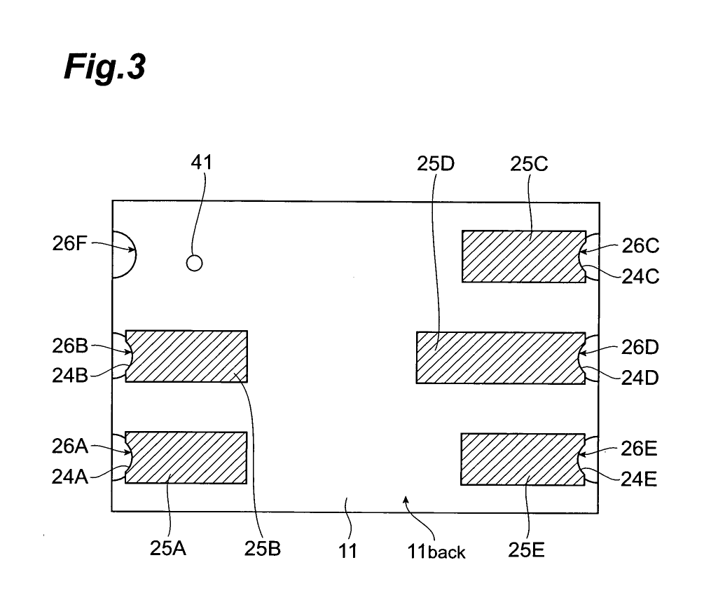

FIG. 1 is a plan view of an optical semiconductor device which is a typical example of the electronic component according to an embodiment. FIG. 2 is a sectional view along line II-II of the optical semiconductor device shown in FIG. 1, and FIG. 3 a back side view of the optical semiconductor device.

As shown in FIGS. 1 and 2, the optical semiconductor device M of the present embodiment has a base member 1 and a glass window 2 which is a lid member. The base member 1 and the glass window 2 are bonded with an adhesive 3 that cures at room temperature, and a quartered photodiode 4 being an optical semiconductor element is mounted on the base member 1. Namely, four signals can be outputted according to incidence of light from the photodiode 4 (multi-channels).

The base member 1 has a 3-layer structure in which three green sheets of ceramic such as alumina ceramic (ceramic plates) are stacked, the lowermost layer forms a substrate body 11 as shown in FIG. 2, and sheets 13, 14 of two layers formed as upper layers on the substrate body 11 make a wall 12. The substrate body 11 is of a rectangular shape on a plan view, and the photodiode 4 is mounted on this substrate body 11.

The wall 12 is composed of the lower wall (sheet) 13 and the upper wall (sheet) 14, and the substrate body 11 and wall 12 are formed by stacking the totally three ceramic plates (green sheets) and baking them.

The glass window 2 is mounted on the top surface of the wall 12 and is bonded thereto with the adhesive 3. Furthermore, an aperture of a recess 15 in the base member 1 is formed in the part surrounded by the wall 12, and this aperture is closed by the glass window 2 whereby the interior of the recess 15 is hermetically sealed.

The glass window 2 is made of borosilicate glass that transmits blue light, and is thus comprised of the material different from the base member 1. The bottom surface of the glass window 2 is bonded onto the top surface of the wall 12 of the base member 1 with the adhesive 3.

Four upper electrode pads 21A, 21B, 21C, and 21E are provided on the top surface of the lower wall 13 in the wall 12.

Furthermore, the photodiode 4 is placed on an electrode pad 21D on the front side of the substrate body 11. Furthermore, the quartered photodiode 4 is provided with four connection electrodes. These four connection electrodes are electrically connected through respective bonding wires 22A, 22B, 22C, and 22E to the upper electrode pads 21A, 21B, 21C, and 21E, respectively.

Four electroconductive portions 23A, 23B, 23C, and 23E are formed in the lower wall 13. Each of these electroconductive portions 23A, 23B, 23C, and 23E electrically connects the upper electrode pad 21A, 21B, 21C, or 21E to a side electrode 24A, 24B, 24C, or 24E and a back electrode terminal 25A, 25B, 25C, or 25E, respectively, shown in FIG. 3. The electrode pad 21D is electrically connected through a side electrode 24D to a back electrode terminal 25D with no connection electrode because it is formed on the top surface of the substrate body 11.

A through hole is formed near the upper wall 14, e.g., at least one of the four corners of the aperture 15, in the same diameter in the lower wall 13 and in the substrate body 11 and in a size enough to prevent the resin from readily flowing out; the hole penetrates the wall and main body to form one through hole 41. The through hole 41 functions as follows: the adhesive for bonding the lid member 2 of glass to the base member 1 flows down the interior wall of the upper wall 14 into the through hole 41 to obstruct the through hole 41, and the adhesive (seal means) 42 is cured in the obstructing state to form a hermetically-sealed space in the recess 15.

The through hole 41 penetrating the lower wall 13 and the substrate body 11 constituting the recess functions as an air vent port to allow air present in each recess to escape to the outside during the bonding of the lid member 2 to the base member 1, particularly, during a process of covering a plurality of recesses in the base member 1 by the lid member 2. Therefore, this solves the problem that there occurs the phenomenon in which air is unlikely to escape to the outside through the clearance between the lid member 2 and the base member 1, so as to cause slipping of the lid member 2 on the surface of the base member 1 and adhesion failure with the adhesive.

Furthermore, when the through hole 41 functioning as an air vent port is provided in the bottom surface near the upper wall 14, the adhesive flowing down the interior wall of the upper wall 14 automatically flows into the through hole 41 and cures there, and it then functions as adhesive 42 to obstruct the through hole 41. This permits the recess 15 to constitute a hermetically-sealed space, so as to assure sufficient moisture resistance. The through hole 41 is continued to the through hole 43.

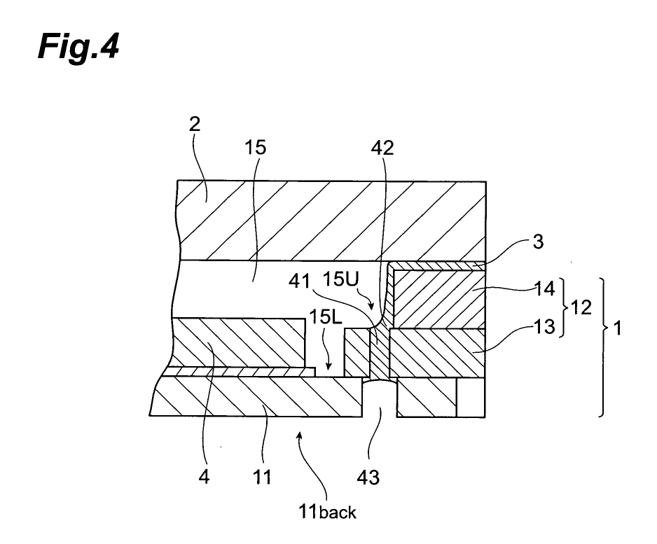

FIG. 4 is a vertical sectional view near the through hole in an optical semiconductor device of the second embodiment. The optical semiconductor device of the second embodiment is different only in the size of the through hole from that of the above-described embodiment.

The through holes 41, 43 formed in the lower wall 13 and in the substrate body 11, respectively, are so sized as to prevent the resin (adhesive) from readily flowing out. The diameter of the through hole 41 formed in the lower wall 13 is smaller than the diameter of the through hole 43 formed in the substrate body 11. When the through holes are so formed that the through hole 41 in the lower wall 13 has the smaller diameter and that the through hole 43 in the substrate body 11 has the larger diameter, the adhesive 42 moving down the wall part and flowing into the through hole 41 can be prevented from flowing out to the outside.

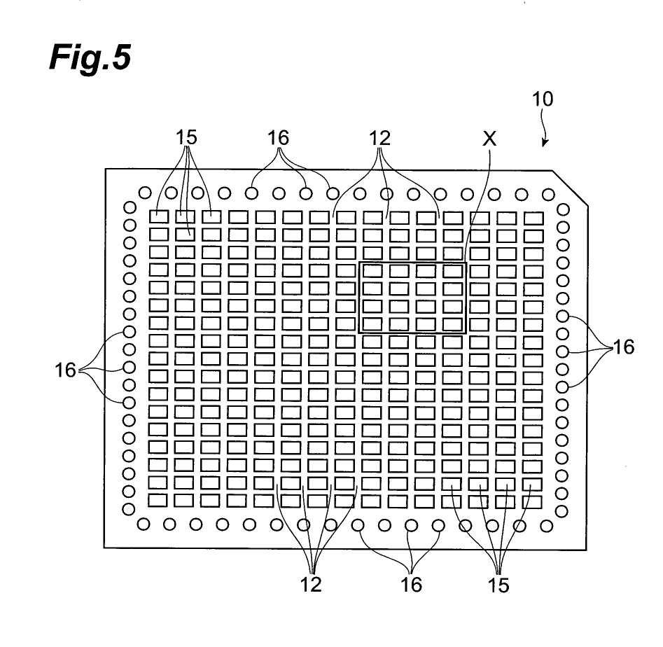

FIG. 5 is a plan view of a sheet substrate 10 consisting of a plurality of base members 1 before separated. Specifically, at least one through hole 41 is formed in each recess 15 of the sheet substrate 10 in which a plurality of recesses 15 are formed as shown in FIG. 5. After the recesses 15 are closed, the sheet substrate 10 is cut to separate the recesses 15 from each other. Dicing lines in this separation are set on opening end faces of the recesses 15, i.e., on top surfaces of walls 12.

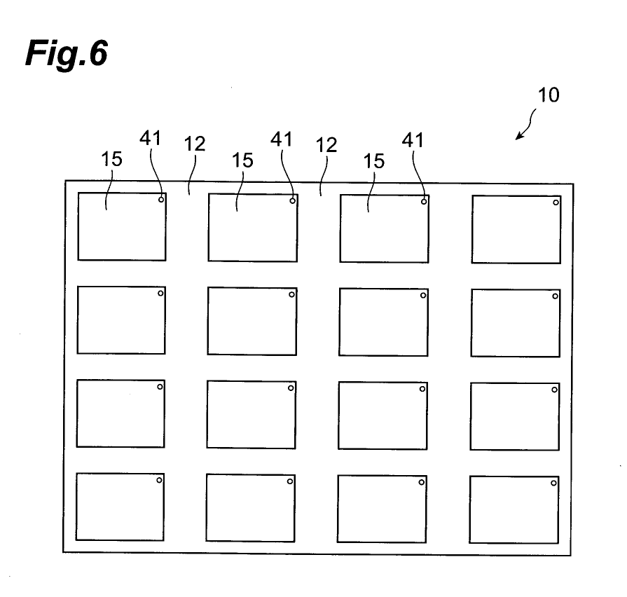

Forming positions of through holes 41 will be described. FIGS. 6 to 8 are enlarged views of the interior of region X in FIG. 5.

As shown in FIG. 6, a preferred configuration is such that a recess-side aperture of through hole 41 is formed near at least one of the four corners of the bottom surface of each recess (apex positions of the bottom surface of the recess). When the lid member 2 of glass is bonded to the base member 1, the lid member is pushed from top in a state in which the adhesive is applied along the upper end of the wall part 12 (opening end face) being ridge part (frame part) of the base member 1. Therefore, the adhesive 3 flows from the ridge part along the interior wall of the upper wall 14 to spread over the upper end of the lower wall 13. On this occasion, the adhesive can readily flow into each through hole 41 to obstruct the through hole 41 and be cured there because the through hole 41 is formed in the bottom surface near the upper wall.

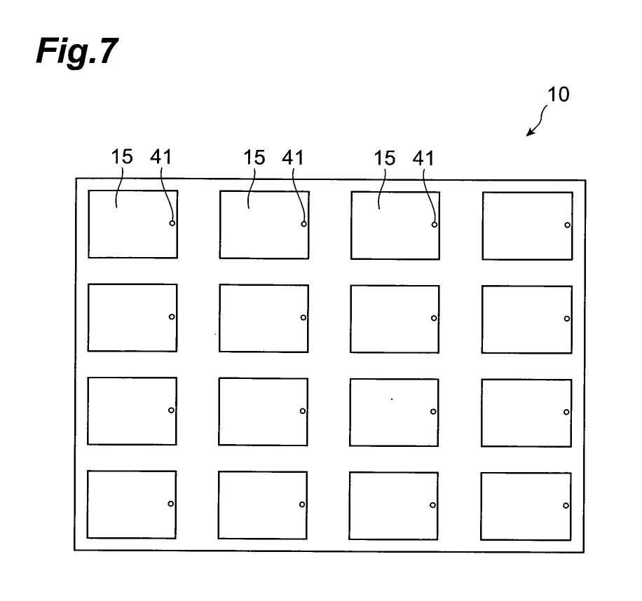

FIG. 6 showed the example in which the through hole 41 is formed near at least one of the four corners of each recess 15, but similar effect can be expected as long as each through hole is formed in the bottom surface near the upper wall surrounding the aperture, as shown in FIG. 7. Namely, a recess-side aperture of through hole 41 is formed near an edge of a polygon constituting the bottom surface of each recess 15. Although not shown, it is needless to mention that the through hole is formed only in the substrate body 11 in a case where the through hole 41 is formed near two edges in a configuration wherein the lower wall 13 is excluded.

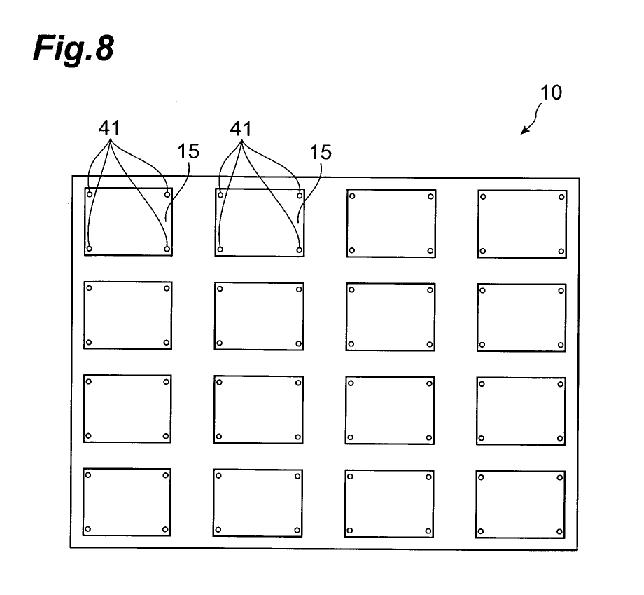

It is needless to mention that similar effect is also achieved where through holes 41 are present at positions near all the four corners of the bottom surface of each recess, as shown in FIG. 8.

Furthermore, as shown in FIG. 3, six depressed surfaces (notches) 26A-26F are formed in the substrate body 11. The depressed surfaces 26A-26F all are formed in the side ends of the substrate body 11. These depressed surfaces 26A-26F have a semicircular shape on a plan view. These depressed surfaces 26A-26F are covered by the back surface of the lower wall 13 (cf. FIG. 2) and, therefore, they cannot be observed from the lid member 2 side.

Side electrodes 24A-24E are formed on the five depressed surfaces 26A-26E, respectively, out of these six depressed surfaces. In the optical semiconductor device M of the present embodiment, the depressed surfaces are formed only in the substrate body 11, but are not formed in the wall 12 bonded to the glass window 2. For this reason, the depressed surfaces 26A-26F are placed at positions except for the surface where the aperture is formed in the base member 1 and, in the present embodiment, they are located at the positions between the front surface and back surface of the substrate body 11. The front surface of the wall 12 being a contact surface with the glass window 2 located on the aperture surface side in the base member 1 is a region where no depressed surface is formed.

Furthermore, an unrepresented antireflection film is formed as a single layer or as multiple layers on each of the front surface and back surface in the glass window 2. These antireflection films prevent reflection of light on the glass window 2 and increase the transmittance of specific wavelengths. The present embodiment adopts the borosilicate glass material that transmits blue light, as the glass window 2, but it is also possible to use a silica glass material or the like that transmits light of shorter wavelengths than the wavelength of blue light. The antireflection film may be formed on one of the front surface and back surface of the glass window 2, or the antireflection film can be excluded.

The adhesive 3 for bonding the base member 1 and the glass window 2 is of the room temperature curing type and, more particularly, it is a moisture curing adhesive; specifically, a moisture curing silicone resin. The moisture curing silicone resin cures at room temperature to demonstrate the bonding effect.

A production method of the optical semiconductor device of the present embodiment having the above-described configuration will be described. The optical semiconductor device of the present embodiment is produced by attaching photodiodes and a sheet lid member as a base material of the lid member to a sheet substrate as a base material of the base member, and dicing the complex.

A sheet substrate 10 as shown in FIGS. 5-8 is prepared in the first step of production of the optical semiconductor device.

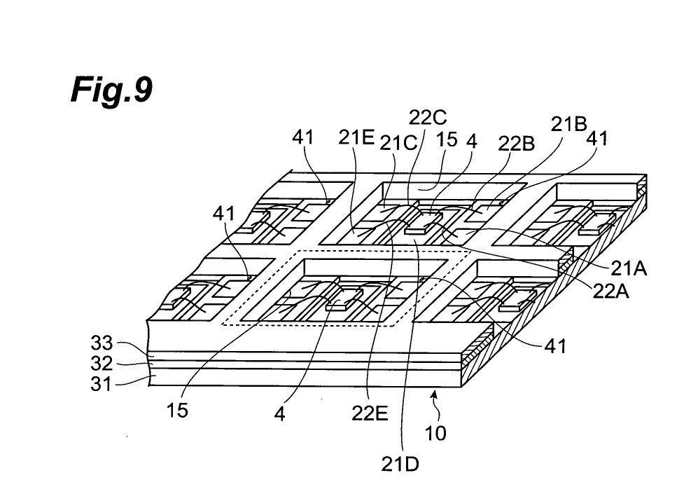

The sheet substrate 10 is formed by laying three ceramic sheets 31 (11), 32 (13), 33 (14) shown in FIG. 9 and baking them. The sheet substrate 10 can be made of a glass epoxy resin or the like, but in the case of handling blue light or the like, organic gas evolves from the glass epoxy resin in a high-temperature process during soldering to attach to the glass window, the photodiode 4, and so on and could cause degradation of sensitivity. In this respect, ceramic being an inorganic substance produces no organic gas and is thus advantageous for that reason.

The first ceramic sheet 31 located as the lowermost layer is provided with no holes for recesses, and is intended to become the substrate body 11 of the base member 1. The second ceramic sheet 32 disposed as an upper layer on the first ceramic sheet 31 is provided with m×n through holes, 17×15=255 through holes in the present embodiment, which are two-dimensionally arranged in a matrix pattern, and the through holes are smaller than apertures of the recesses 15 formed in the base member 1. This second ceramic sheet 32 becomes the lower wall 13 in the wall 12 of the base member 1. The arrangement of the recesses may be one-dimensional.

The third ceramic sheet 33 located as an upper layer on the second ceramic sheet 32 is also provided with 255 through holes arranged at positions corresponding to the through holes in the second ceramic sheet 32 and in a matrix pattern, and the through holes are holes in the same size as the apertures of the recesses 15 formed in the base member 1. This third ceramic sheet 33 becomes the upper wall 14 in the wall 12 of the base member 1. The first ceramic sheet 31 and the second ceramic sheet 32 are provided with through holes 41 (43) functioning as air vent holes, each near the position corresponding to the upper wall 33 (14).

Through holes (circular holes) to become notches are formed in the first ceramic sheet 31 which becomes the substrate body 11, and metal layers for formation of the side electrodes 24A-24E are formed on inner walls of the through holes. Furthermore, metal layers for formation of the electrode terminals 25A-25E are formed on the back surface. These three ceramic sheets 31-33 are stacked and baked, and thereafter the metal layer parts exposed to the outside are plated with gold.

Photodiodes 4 are mounted on the electrode pads 21D in the respective recesses 15 of this sheet substrate 10. During the mounting of photodiodes 4, they are die-bonded, e.g., with an electroconductive adhesive or the like so that each electrode pad 21D is connected to a cathode common electrode (not shown) on the back side of photodiode 4, and electrodes of respective channels on the front side of each photodiode 4 are wire-bonded to the electrode pads formed on the lower wall 13 in the present embodiment, in order to connect anodes. In this way, the electrical connection is completed between the sheet substrate 10 (base member 1) and the photodiode 4 in each of the 17×15 recesses 15 in the sheet substrate 10.

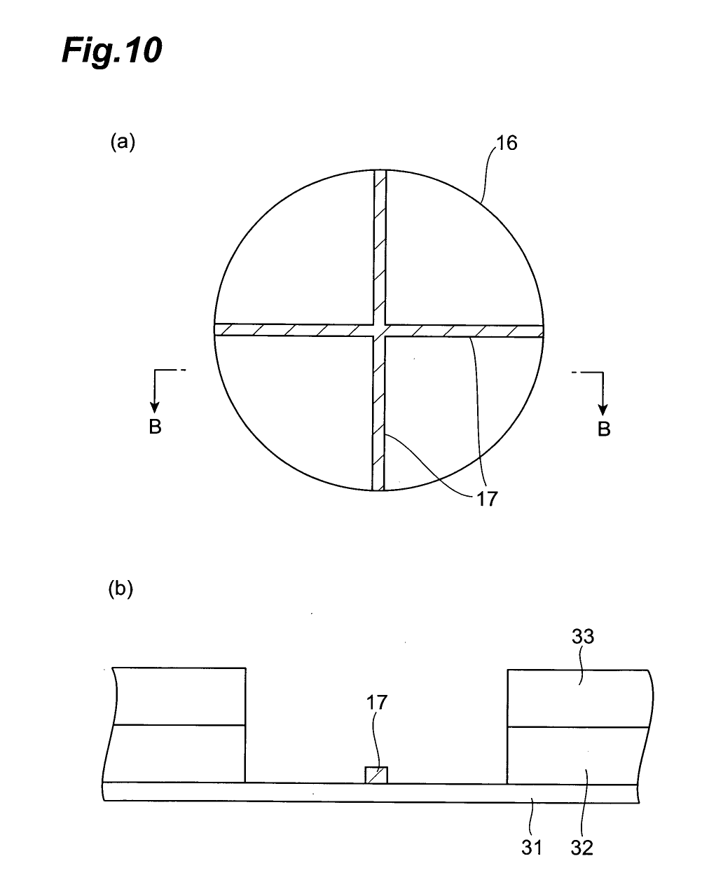

A plurality of counterbores 16 are formed in the sheet substrate 10 (cf. FIG. 5), and the counterbores 16 penetrate the third ceramic sheet 33 and the second ceramic sheet 32 down to the front surface of the first ceramic sheet 31. A marker 17 of a metal wire in a cross shape indicating a pitch center between recesses 15 is placed, as shown in (a) of FIG. 10, on the front surface of the first ceramic sheet 31 and in each counterbore 16. Each marker 17 of the metal wire is patterned as shown in (b) of FIG. 10 on the same front surface as the electrode pads 21D are formed, and coincides with centers of the through holes (circular holes) to become notches.

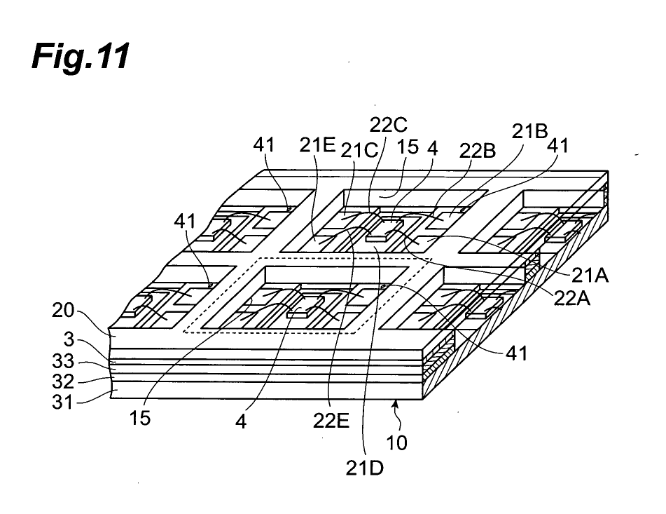

After the sheet substrate 10 is prepared as described above, the adhesive 3 is applied onto the top surface of the upper layer forming the wall 12 surrounding the periphery of each recess 15 in the sheet substrate 10 equipped with the photodiodes 4, as shown in FIG. 11. This adhesive 3 is a moisture curing silicone resin. A sheet lid member 20 is bonded to the top surfaces of the walls 12 so as to cover all the recesses 15 in the sheet substrate 10, with this adhesive 3, to seal the apertures of the recesses 15 with the sheet lid member 20. In the same drawing, the sheet lid member 20 is illustrated so as to see the underlying members through it.

In this sheet substrate 10, the through holes to become the notches are formed only in the first ceramic sheet 31 of the lowermost layer, and no through holes are formed in the other layers including the uppermost layer to which the sheet lid member 20 is bonded. This can prevent the adhesive 3 used in bonding of the sheet lid member 20, from flowing out through the through holes to the back side of the sheet substrate 10. If the adhesive 3 should flow out to the back side of the sheet substrate 10 where the electrode terminals 25A-25E are formed, there would arise a problem that soldering cannot be implemented on the gold-plated surfaces of the electrode terminals 25A-25E. In this respect, the present embodiment does not pose this problem because the adhesive is prevented from flowing through the through holes on the back side of the substrate body 11.

A through hole is formed in the same size in each of the lower wall 13 and the substrate body 11 and in a size enough to prevent the resin from readily flowing out (i.e., in the outside diameter of not more than 2 mm), in the bottom surface near the upper wall 14, e.g., near at least one of the four corners of each aperture 15, and each through hole penetrates the lower wall and the substrate body to constitute one through hole 41. It is noted that a size of a hole is given as an average size of the hole, independent of the shape of the hole, e.g., a circle, a rectangle, or the like.

The through hole 41 functions as follows: the adhesive for bonding the lid member 2 of glass to the base member 1 flows down the interior wall of the upper wall 14, spreads over the top surface of the lower wall 13, flows into the through hole 41 to obstruct it, and is cured as seal means 42 in the obstructing state to form a hermetically-sealed space in each recess 15.

Namely, in the present invention, the through holes 41 penetrating the lower wall 13 and the substrate body 11 forming the recesses function as air vent holes for allowing air present in each recess 15 to escape to the outside during the bonding of the lid member 2 to the base member 1, particularly, during the process of covering the plurality of recesses in the sheet substrate (base member) 10 by the sheet lid member 2, whereby the air is prevented from flowing through the clearance between the lid member 2 and the base member 1 to the outside, which solves the problems that there occurs the phenomenon in which the lid member 2 slides on the front surface of the base member 1 and that the adhesive fails to attach.

In addition, each through hole 41 functioning as an air vent hole is provided in the bottom surface near the upper wall 33 (14) and thus the adhesive flowing down the upper wall 33 (14) automatically flows into the through hole, cures therein, and functions as a seal member 42 obstructing the through hole, whereby the recess 15 can automatically construct a hermetically-sealed space, without need for carrying out a separate step of obstructing the through hole 41, while sufficient moisture resistance is assured.

The room temperature curing adhesive 3 is used when the sheet lid member 20 is bonded to the sheet substrate 10. Since this adhesive 3 cures at room temperature, there is no need for exposing the adhesive under high temperature, and it can reduce stress due to the difference between expansion coefficients of the glass window 2 and the base member 1 occurring after bonded. Therefore, even silica glass (glass window 2) and alumina ceramic (base member 1) with the expansion coefficients different by one digit, can be bonded with certainty, while preventing peeling or bonding failure.

Particularly, the moisture curing silicone resin reacts with hydroxyl (—OH) of an adhering object to effect bonding. For this reason, it is a very suitable adhesive for bonding between glass and ceramic. The silicone resin still maintains sufficient flexibility even after cured and has low hygroscopicity, different from the epoxy resin adhesives and others. Furthermore, it has a property of very high heat resistance among resins, and thus it can prevent peeling of the sheet lid member, a drop of the sheet lid member, etc. during soldering.

Furthermore, the adhesive 3 cures at room temperature and thus can prevent the situation in which air in each recess 15 in the hermetically-sealed state becomes swollen during the curing to generate voids in the bonding surface and cause curing failure. Since the silicone resin is highly transparent to light in the short wavelength range, degradation will not occur in the photodetection sensitivity of photodiodes 4 even if a small amount of the adhesive attaches to the photodetecting portion.

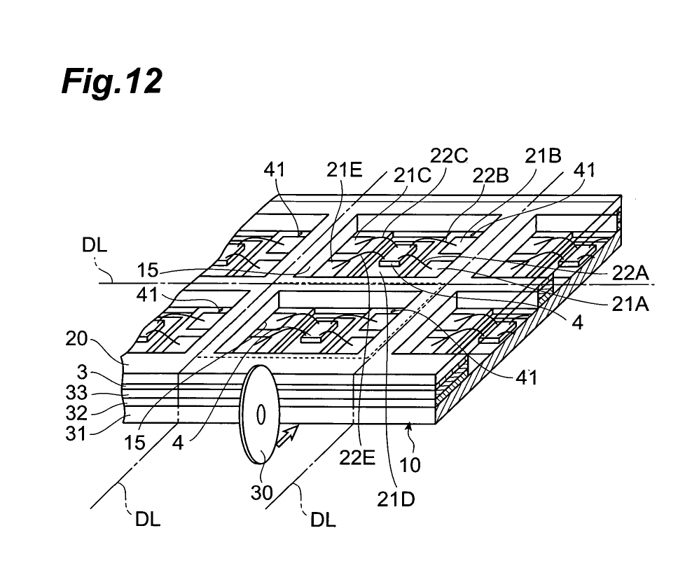

After the sheet lid member 20 is bonded to the sheet substrate 10 in this manner, dicing is performed with a dicing blade 30 to dice the sheet substrate 10, the sheet lid member 20, and the adhesive 3 all together in units of the recesses 15, as shown in FIG. 12. The dicing is performed while the dicing blade 30 is aligned with the markers 17 of the metal wire in the cross shape inside the through holes of counterbores 16 around the recesses 15 arranged in the matrix pattern, in the sheet substrate 10. In FIG. 12 three dicing lines DL are indicated by chain lines.

By simultaneously cutting the sheet substrate 10 and the sheet lid member 20 of the matrix pattern with the dicing blade 30 as described above, the recesses 15 with 17×15 photodiodes 4 are separated to obtain 255 semiconductor devices M. The markers 17 of the metal wire in the cross shape for alignment are formed as patterns in the same layer as the electrode pads 21D for die bonding of the optical semiconductor devices M. For this reason, the positional reference for cuffing into the optical semiconductor devices M is coincident with the positional reference for die bonding of the optical semiconductor elements in the optical semiconductor devices M. Therefore, it is feasible to improve the positional accuracy of the optical semiconductor elements relative to the contour reference of the optical semiconductor devices M.

The markers 17 are set as follows: they pass at least the upper layer of the sheet substrate 10 and the dicing blade passes approximately the centers of the through holes (circular holes) for notches formed in the lower layer. After the dicing is performed in this manner, the through holes are exposed in part to the outside, and appear as notches at the side edges of the optical semiconductor devices M.

As the base member 1 and glass window 2 are cut with the dicing blade 30, the devices are produced in a state in which the base member 1 and glass window 2 are bonded to each other. For this reason, the side edges of the base member 1, glass window 2, and adhesive 3 are aligned with each other along a continuously linear plane. This can prevent occurrence of problems of chipping and protrusion of the end face of the base member 1, and thus it can achieve a compact structure and facilitate alignment with another component.

In the optical semiconductor devices M formed in this manner, the room temperature curing adhesive 3 is used to bond the base member 1 and the glass window 2 to hermetically seal the photodiode 4 in an airtight state in the recess 15. For this reason, thermal stress is unlikely to occur and it becomes feasible to adapt to high-temperature lead-free soldering. Since the silicone resin used in the bonding between the base member 1 and the glass window 2 has sufficient flexibility even after cured, high-temperature soldering can be performed, without need for forming a vent hole in the base member 1.

Furthermore, when the glass window 2 is made of silica glass, the optical semiconductor devices of the surface mount type for light of short wavelength such as blue can be produced. It also becomes easier to implement surface mount of a large-area semiconductor element. In addition, when the glass window is made of color glass or glass with an interference film, the optical semiconductor elements can be fabricated as elements with a band-pass filter for selecting a specific wavelength. The optical semiconductor elements can also be light emitting devices such as laser diodes.

As described above, the foregoing electronic component has the following structural advantages.

Firstly, as shown in FIG. 2, the foregoing electronic component is provided with the base member 1 having the through hole 41 (43) extending from the bottom surface of the recess 15 to the back surface 11_{back}, the electronic element 4 mounted in the recess 15, the lid member 2 closing the aperture of the recess 15, and the adhesive 3 (42) interposed between the lid member 2 and the opening end face of the recess 15, and obstructing the through hole 41 (43) to keep the interior space of the recess in the hermetically-sealed state.

Therefore, the adhesive 3 (42) obstructs the space between the lid member 2 and the base member 1, and the adhesive 3 (42) finally also obstructs the through hole 41 (43) penetrating from the bottom surface of the recess 15 to the back surface 11_{back}, so as to allow air, which could inhibit the obstruction, to escape during the production. Since the inhibition of adhesion with the adhesive 3 (42) due to air is prevented in this manner, the positional deviation and adhesion failure are suppressed and the obstruction with the adhesive achieves better hermetic sealing in the recess than before. The effect is prominent, particularly, in cases of materials having a plurality of recesses.

Secondly, as shown in FIGS. 6 to 8, the aperture on the recess side of the through hole 41 is located in the bottom surface near the interior wall of the recess 15. In this case, the adhesive 3 located on the opening end face (12) of the recess can readily enter the interior of the aperture of the through hole 41 located near the interior wall (within 2 mm), during the production, and thus the adhesive 3 efficiently obstructs the through hole 41, whereby the hermetically-sealed state with the adhesive 3 is improved more than before. The effect is prominent, particularly, in cases of materials having a plurality of recesses.

Thirdly, as shown in FIGS. 6 and 8, the bottom surface of the recess 15 is polygonal (quadrangular in the present example), and the aperture on the recess 15 side of the through hole 41 is located near a position of an apex of the bottom surface (within 2 mm). Since the wall surfaces (side faces) in the recess come to intersect at the position of the apex of the bottom surface, liquid tends to be likely to gather in a narrow space like the space between these side faces. Therefore, the adhesive 3 (43) located on the opening end face of the recess can readily enter the interior of the aperture of the through hole through the gathering-prone space during the production, and thus the adhesive 3 (42) efficiently obstructs the through hole 41, whereby the hermetically-sealed state with the adhesive 3 (42) is improved more than before. This effect is prominent, particularly, in cases of materials having a plurality of recesses.

Fourthly, as shown in FIG. 2, the adhesive 3 (42) continuously hangs down from the region between the lid member 2 and the opening end face (top surface of 12), along the interior wall of the recess, and to the region in the through hole 41. Therefore, the adhesive 3 (42) becomes less likely to depart from the interior of the through hole 41, which improves the reliability of hermetic sealing.

Fifthly, as shown in FIG. 4, the bottom surface of the recess 15 has the lower bottom face 15L to which the electronic element 4 is die-bonded, and the upper bottom face 15U located around the lower bottom face 15L, located nearer the lid member 2 than the lower bottom face 15L, and making the level difference at the border with the lower bottom face 15L, and the through hole 41 (43) extends from the upper bottom face 15U to the back surface 11_{back} of the base member 1. The diameter of the aperture on the back side of the through hole 43 is larger than the diameter of the aperture of the through hole 41 on the recess side. The adhesive 42 flowing from the inner surface side of the recess 15 into the through hole 41 obstructs the through hole 41 on the smaller diameter side, and even if the amount of adhesive 42 is excessive, the adhesive 42 is less likely to flow over the back surface because the adhesive-receiving space in the through hole is increased with travel of the adhesive 42 toward the back surface.

Sixthly, the electronic element 4 is an optical semiconductor element, the lid member 2 is made of the material (borosilicate glass) that transmits the major light component (blue light) corresponding to the optical semiconductor element, and the base member 1 is made of the material (alumina ceramic) having the transmission characteristic different from that of the lid member 2; then the base member 1 blocks the major light component, while the lid member 2 transmits the major light component.

Seventhly, the adhesive 3 (42) is the room temperature curing adhesive and, preferably, this adhesive is comprised of the moisture curing silicone resin. Since this adhesive cures at room temperature, there is no need for exposing the adhesive under high temperature, and thus it can reduce stress due to the difference between the expansion coefficients of the lid member and the base member occurring after bonded. Particularly, the moisture curing silicone resin reacts with hydroxyl (—OH) of the adhering object to effect bonding. The silicone resin demonstrates sufficient flexibility even after cured, and also demonstrates low hygroscopicity, different from the epoxy resin adhesives and others. Furthermore, it has the property of very high heat resistance among resins, and thus can prevent peeling of the sheet lid member, a drop of the sheet lid member, etc. during soldering.

Furthermore, since the adhesive cures at room temperature, it is also feasible to prevent the situation in which air in the recess in the hermetically-sealed state becomes swollen during curing to generate voids in the bonding surface and to cause curing failure. Since the silicone resin is highly transparent to light in the short wavelength range, reduction in the transmittance of the light corresponding to the optical semiconductor element can be suppressed even if a small amount of the adhesive attaches to the photodetecting portion.

Eighthly, the base member 1 is made of ceramic. Ceramic is a substance with excellent heat resistance and excellent durability and has the advantage of high adhesion to the silicone resin.

Ninthly, as shown in FIGS. 1 and 3, the electronic component is provided with the upper electrode pad 21A, 21B, 21C, 21E provided on the bottom surface of the recess 15 and electrically connected to the electronic element 4, and the back electrode terminal 25A, 25B, 25C, 25E provided on the back surface 11_{back} of the base member 1; the upper electrode pad 21A, 21B, 21C, 21E and the back electrode terminal 25A, 25B, 25C, 25E are electrically connected through the conductor 24A, 24B, 24C, 24E on the depressed surface located in the side of the base member 1; the deepest portion of the depressed surface is located outside the outer edge OL (cf. FIG. 2) defining the bottom surface of the recess 15.

In this case, since the deepest portion of the depressed surface is located outside the outer edge OL defining the bottom surface of the recess 15, there is an advantage that the depressed surface is protected from attachment of the adhesive.

The electronic element 4 is connected to the upper electrode pad 21A, 21B, 21C, 21E by a bonding wire or the like, and the upper electrode pad is connected through the conductor 24A, 24B, 24C, 24E provided on the depressed surface, to the back electrode terminal 25A, 25B, 25C, 25E. When the optical semiconductor device M is placed on a circuit wiring board, the back electrode terminals 25A, 25B, 25C, 25E can be connected onto circuit wiring. The conductors 24A, 24B, 24C, 24E on the depressed surfaces in the side can be produced by perforating holes through the substrate and thereafter providing an electroconductive material thereon, and thus production is easy. In this perforating step the holes including the depressed surfaces are made at the positions off the recess forming position so as to maintain the hermetic sealing in the recess, and thereafter the dicing is performed across the holes.

The following modification example may also be adopted.

Tenthly, as shown in FIGS. 1 and 3, the electronic component is provided with the upper electrode pad 21A, 21B, 21C, 21E provided on the bottom surface of the recess 15 and electrically connected to the electronic element 4, and the back electrode terminal 25A, 25B, 25C, 25E provided on the back surface 11_{back} of the base member 1; the upper electrode pad 21A, 21B, 21C, 21E and the back electrode terminal 25A, 25B, 25C, 25E may be electrically connected through the conductor 23A, 23B, 23C, 23E located in the base member 1. In this case, these conductors are located outside the outer edge OL (cf. FIG. 2) defining the bottom surface of the recess 15.

In this case, since the conductors are located outside the outer edge OL defining the bottom surface of the recess 15, the surfaces of the conductors are not exposed in the recess 15 to achieve the advantage of secure hermetic sealing of the recess 15.

The electronic element 4 and the upper electrode pad 21A, 21B, 21C, 21E are connected by a bonding wire or the like, and the upper electrode pad is connected to the back electrode terminal 25A, 25B, 25C, 25E through the conductor 23A, 23B, 23C, 23E located in the base member 1. When the optical semiconductor device M is placed on a circuit wiring board, the back electrode terminals 25A, 25B, 25C, 25E can be connected onto circuit wiring. The conductors 23A, 23B, 23C, 23E located in the base member can be made by perforating holes through the substrate and providing an electroconductive material in them, and thus production is easy. In this perforating step, the holes are made at the positions off the recess forming position so as to maintain the hermetic sealing in the recess, and thereafter, the holes are filled with the conductor. Then the conductors are covered by the substrate located on the substrate as the bottom surface, to constitute the base member.

The above-described production method of the electronic component has the following advantages in terms of steps.

Firstly, the above-described production method includes the first step of mounting the electronic element 4 in the recess 15 in the base member 1 in which at least one through hole 41 is formed in the bottom surface near the interior wall of the recess 15, and the second step of bonding the lid member 2 to the base member 1 with the room temperature curing adhesive 3 to close the aperture of the recess 15 in the base member 1 by the lid member 2.

When the aperture is closed by the lid member 2, air in the recess flows through the through hole 41 to the outside, which can reduce the positional deviation between the lid member 2 and the base member 1 and the adhesion failure with the adhesive. Since the adhesive 3 (42) also enters the interior of the through hole 41, the hermetic sealing in the recess 15 can be further improved. Since the adhesive is of the room temperature curing type, it is also feasible to prevent the situation in which air in the recess in the hermetically-sealed state becomes swollen during the curing to generate voids in the bonding surface and cause curing failure.

If air in the recess is evacuated through the through hole 41 (43), evacuation of air and suction of the adhesive can be efficiently performed.

Secondly, the first step has the step of preparing the sheet substrate 10 in which a plurality of recesses 15 are formed in the same surface, and the step of mounting the electronic element 4 in each of these recesses 15, and the second step has the step of applying the room temperature curing adhesive 3 onto the opening end face of each recess 15, and the step of pasting the sheet substrate 10 and the sheet lid member 20 together with the adhesive 3, whereby the adhesive 3 flows down the interior wall of the recess into at least one through hole 41 extending from the bottom surface of each recess 15, so as to obstruct the through hole 41 (43), thereby forming the complex sheet (compound shown in FIG. 12) in which the spaces in the recesses are in the hermetically-sealed state.

This production method has the step of cutting the complex sheet comprised of the sheet substrate 10, the sheet lid member 20, and the adhesive 3, along dicing lines DL set on regions between the recesses, to separate cut portions, and the cutting results in obtaining a plurality of electronic components in each of which the base member 1 and the lid member 2 are pasted together.

Air in the recess 15 flows through the through hole 41 to the outside and, at the same time, the adhesive 3 (42) flows down the interior wall of the recess into the through hole 41 to obstruct it, and cures at room temperature. When the complex sheet is cut along the dicing lines DL on the regions between the recesses, a plurality of electronic components can be obtained with sufficient hermetic sealing in the recess.

### INDUSTRIAL APPLICABILITY

The present invention is applicable to any electronic component with an electronic element and production method thereof.

1. An electronic component comprising:
a base member having a through hole extending from a bottom surface of a recess to a back surface;
an electronic element mounted in said recess;
a lid member closing an aperture of said recess; and
an adhesive interposed between said lid member and an opening end face of said recess and obstructing the through hole to keep an interior space of said recess in a hermetically-sealed state.

2. The electronic component according to claim 1, wherein an aperture on said recess side of said through hole is located near an interior wall of said recess.

3. The electronic component according to claim 2, wherein the bottom surface of said recess is polygonal, and
wherein said aperture on said recess side of said through hole is located near a position of an apex of said bottom surface.

4. The electronic component according to claim 1, wherein said adhesive continuously hangs down from a region between said lid member and said opening end face, along an interior wall of the recess, and to a region in said through hole.

5. The electronic component according to claim 1, wherein said bottom surface of said recess has:
a lower bottom face to which the electronic element is die-bonded; and
an upper bottom face located around said lower bottom face, set nearer said lid member than said lower bottom face, and making a level difference at a border with said lower bottom face,
wherein said through hole extends from said upper bottom face to said back surface of said base member, and
wherein a diameter of an aperture on said back surface side of said through hole is larger than a diameter of said aperture on said recess side.

6. The electronic component according to claim 1, wherein said electronic element is an optical semiconductor element,
wherein said lid member is comprised of a material that transmits a major optical component corresponding to said optical semiconductor element, and
wherein said base member is comprised of a material having a different transmission characteristic from that of said lid member.

7. The electronic component according to claim 1, wherein said adhesive is an adhesive comprised of a room temperature curing silicone resin.

8. The electronic component according to claim 1, wherein said base member is made of ceramic.

9. The electronic component according to claim 1, comprising:
an upper electrode pad disposed on said bottom surface of said recess and electrically connected to said electronic element; and
a back electrode terminal disposed on said back surface of said base member,
wherein said upper electrode pad and said back electrode terminal are electrically connected through a conductor on a depressed surface located in a side of said base member, and a deepest part of said depressed surface is located outside an exterior edge defining said bottom surface of said recess.

10. The electronic component according to claim 1, comprising:
an upper electrode pad disposed on said bottom surface of said recess and electrically connected to said electronic element; and
a back electrode terminal disposed on said back surface of said base member,
wherein said upper electrode pad and said back electrode terminal are electrically connected through a conductor located in said base member, and said conductor is located outside an exterior edge defining said bottom surface of said recess.

11. A method of producing an electronic component, comprising:
a first step of mounting an electronic element in a recess in a base member in which at least one through hole is formed in a bottom surface near an interior wall of said recess; and
a second step of bonding a lid member to said base member with a room temperature curing adhesive to close an aperture of said recess in said base member by said lid member.

12. The method according to claim 11, wherein said first step has:
a step of preparing a sheet substrate in which a plurality of recesses are formed in one surface; and
a step of mounting said electronic element in each of said plurality of recesses, and
wherein said second step has:
a step of applying said room temperature curing adhesive onto an opening end face of each recess; and
a step of pasting said sheet substrate and a sheet lid member together with said adhesive to let said adhesive flow down said interior wall of said recess into said at least one through hole extending from said bottom surface of each recess, and thereby obstructing said through hole to form a complex sheet in which an interior space of said recess is kept in a hermetically-sealed state,
said method comprising a step of cutting said complex sheet consisting of said sheet substrate, said sheet lid member, and said adhesive, along a dicing line set on a region between said recesses, wherein this cutting results in obtaining a plurality of electronic components in each of which said base member and said lid member are pasted together.
